(19) United States
(12) Patent Application Publication
(10) Pub. No.: US 2026/0190941 A1
(43) Pub. Date: Jul. 2, 2026

(54) WAFER MOUNT AND METHOD OF MANUFACTURING WAFER MOUNT

(71) Applicant: NGK INSULATORS, LTD., Nagoya-shi (JP)

(72) Inventors: Natsuki HIRATA, Nagoya-shi (JP); Shinya YOSHIDA, Nagoya-shi (JP); Toshiki KONDO, Toyokawa-shi (JP)

(21) Appl. No.: 19/546,795

(22) Filed: Feb. 23, 2026

Related U.S. Application Data
(63) Continuation of application No. PCT/JP2023/034341, filed on Sep. 21, 2023.

(51) Int. Cl. H10P 72/72; B32B 15/04; B32B 37/12; H01J 37/32

(52) U.S. Cl. CPC H10P 72/722; B32B 15/04; B32B 37/1207; B32B 2037/1223; H01J 37/32724; H01J 2237/002; H01J 2237/2007

(57) ABSTRACT

A wafer mount to which a wafer is mounted and fixed includes: an electrostatic chuck including a ceramics base body including a wafer mounting surface and an ESC electrode and a heater electrode each buried inside the ceramics base body; a cooling plate made of metal; and a bonding sheet made of resin to bond the electrostatic chuck and the cooling plate, wherein a bonding surface of the electrostatic chuck bonded to the bonding sheet has an uneven structure made up of one type or plural types of unit structures, and in the uneven structure, a protrusion is provided at a pitch equal to or larger than 100 μm and equal to or smaller than 300 μm.

### CROSS-REFERENCE TO RELATED APPLICATION

This application is a continuation application of PCT/JP2023/034341, filed on Sep. 21, 2023, the entire content of which is incorporated herein by reference.

### BACKGROUND

### Technical Field

The present invention relates to a wafer mount that fixes a workpiece such as a wafer via electrostatic attraction, and particularly to bonding of an electrostatic chuck thereof.

### Description of the Background Art

Already known is a wafer mount (also referred to as an electrostatic chuck, for example) that fixes a semiconductor wafer (also simply referred to as a wafer hereinafter) via electrostatic attraction when predetermined processing such as plasma processing is performed (for example, refer to Japanese Patent Application Laid-Open No. 2020-53460 and Japanese Patent No. 5891332).

The wafer mount substantially has a configuration that a ceramics base body (ceramics member) into which an electrostatic chuck electrode (ESC electrode) for electrostatically attracting a wafer and a heater electrode for heating the wafer are buried and a cooling plate (also referred to as a base table, for example) including inside a flow path in which a coolant for cooling the ceramics base body flows are bonded by a bonding layer.

In such a wafer mount, when DC voltage is applied to the ESC electrode while the wafer is disposed on the mounting surface as an upper surface of the ceramics base body, the wafer is fixed via electrostatic attraction. In addition, when power conduction is performed on the heater electrode while the coolant flows in the flow path inside the cooling plate, the wafer is heated with a predetermined temperature distribution (heat uniformity distribution) which has been preset.

In the wafer mount described above, since the heater electrode is provided to obtain a heat generation density compensating a heat extraction distribution, a desired temperature distribution is ensured.

However, there is a case where an assumed heat generation density cannot be obtained due to occurrence of variation in a shape (a cross-sectional area and a width, for example) of the heater electrode from designed one. Because of such a factor, a temperature distribution on a wafer surface fixed to the wafer mount may be different for each individual. A wafer mount in which a desired temperature distribution cannot be obtained may also be manufactured according to circumstances.

A heat extraction distribution in the wafer mount may be different for each individual also depending on a thickness variation of a bonding layer and processing accuracy of a cooling plate, for example. Particularly, when a bonding sheet made up of sheet-like resin is used as the bonding layer, there is a case where a distribution occurs in heat resistance due to a thickness variation of the bonding sheet, and heat uniformity of the wafer mount is deteriorated.

### SUMMARY

The present invention relates to a wafer mount on which a workpiece such as a wafer is fixed via electrostatic attraction, and particularly to bonding of an electrostatic chuck thereof.

According to the present invention, a wafer mount to which a wafer is mounted and fixed includes: an electrostatic chuck including: a ceramics base body including a wafer mounting surface; and an ESC electrode and a heater electrode each buried inside the ceramics base body; a cooling plate made of metal; and a bonding sheet made of resin sandwiched between the electrostatic chuck and the cooling plate to bond the electrostatic chuck and the cooling plate, wherein a bonding surface of the electrostatic chuck bonded to the bonding sheet has an uneven structure made up of one type or plural types of unit structures, and in the uneven structure, a protrusion is provided at a pitch equal to or larger than 100 μm and equal to or smaller than 300 μm, and the bonding surface includes a distal end surface of the protrusion.

According to the invention, provided is a wafer mount excellent in heat conductivity compared with a case with no uneven structure. Particularly, since heat transmission from the protrusion is dominant in heat transmission from the electrostatic chuck to the cooling plate, heat transmission from the electrostatic chuck to the cooling plate efficiently occurs compared with a case with no uneven structure.

Accordingly, an object of the present invention is to provide a wafer mount excellent in heat uniformity compared with a conventional wafer mount.

### BRIEF DESCRIPTION OF THE DRAWINGS

FIG. 1 is a schematic cross-sectional view along a thickness direction of a wafer mount 10.

FIG. 2A and FIG. 2B are schematic views for each explaining a detailed structure of a bonding part between an electrostatic chuck 20 and a bonding sheet 40.

FIG. 3 is a diagram exemplifying uneven structures 25 with two patterns in which shapes of a protrusion 23 and a recess 24 are different from each other.

FIG. 4 is a diagram for explaining a variation correction of a temperature.

FIG. 5A to FIG. 5D are diagrams each illustrating an actually-measured cross-sectional shape profile of the electrostatic chuck 20.

FIG. 6A and FIG. 6B are diagrams for each explaining specific contents of the temperature variation correction.

FIG. 7 is a diagram illustrating a temperature distribution image IM2 in a mounting surface 20a of the wafer mount 10 made up using a correction target electrostatic chuck 20.

FIG. 8A and FIG. 8B are diagrams each illustrating formation of a high rib structure 25H.

FIG. 9A to FIG. 9C are diagrams each illustrating formation of a low rib structure 25L.

FIG. 10A and FIG. 10B are diagrams each schematically illustrating the wafer mount 10 with a thickness variation in the bonding sheet 40.

FIG. 11A and FIG. 11B are diagrams each schematically illustrating the wafer mount 10 in which the uneven structure 25 corresponding to the thickness variation of the bonding sheet 40 is provided to the electrostatic chuck 20.

FIG. 12A and FIG. 12B are diagrams for each explaining a thickness absorption high rib structure 25H.

FIG. 13A and FIG. 13B are diagrams for each explaining a thickness absorption low rib structure 25L.

### DESCRIPTION OF THE PREFERRED EMBODIMENTS

### <Wafer Mount>

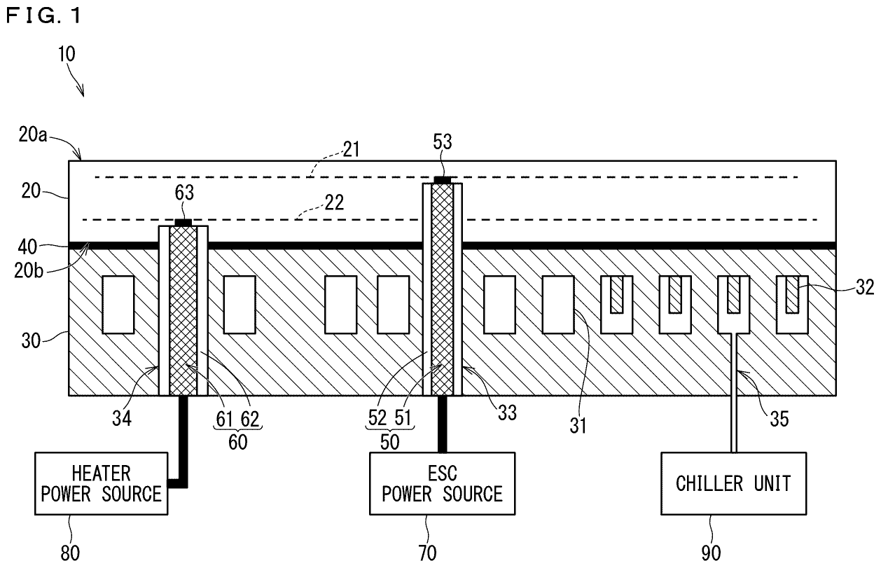

FIG. 1 is a schematic cross-sectional view along a thickness direction of a wafer mount 10 illustrating a configuration of the wafer mount 10 according to an embodiment of the present invention. The wafer mount 10 substantially has a configuration that an electrostatic chuck 20 and a cooling plate 30 are bonded by a bonding sheet 40, thus are disposed to be stacked to each other. The wafer mount 10 is also referred to as a susceptor, and fixes a semiconductor wafer (wafer) as an aspect of a workpiece with the electrostatic chuck 20 in performing predetermined processing such as plasma processing on the wafer.

The electrostatic chuck 20 has a configuration that an electrostatic chuck electrode (ESC electrode) 21 for electrostatically attracting the wafer is buried into a plate-like (for example, a disc-like) ceramics base body made of insulative ceramics such as Al₂O₃ or AlN. A heater electrode 22 for heating the wafer is also buried into the electrostatic chuck 20 illustrated in FIG. 1. Such an electrostatic chuck 20 is also referred to as an electrostatic chuck heater. In the electrostatic chuck 20 illustrated in FIG. 1, the ESC electrode 21 is buried closer to a mounting surface 20a than the heater electrode 22. A main surface of the electrostatic chuck 20 on a side opposite to a bonding surface 20b bonded to the bonding sheet 40 is the mounting surface 20a on which the wafer is disposed.

Metal such as W, Mo, Ti, Si, or Ru or carbide or nitride thereof is exemplified as a material of the ESC electrode 21 and the heater electrode 22.

The cooling plate 30 is a portion including a flow path 31 inside and introducing a coolant (for example, water) to the flow path 31 from outside, thereby cooling the electrostatic chuck 20 and further a wafer fixed to the mounting surface 20a thereof via electrostatic attraction. A preferable example of the flow path 31 is one continuous groove part spirally provided in a plan view so that substantially a whole region of the electrostatic chuck 20 is cooled. Also applicable is that a plurality of individual open circular groove parts are concentrically provided in a plan view.

Although a metal material such as aluminum is preferably used as a material of the cooling plate 30, also applicable is that ceramics or a composite material of metal and ceramics is used.

A fin 32 may be provided to protrude on at least one position of the flow path 31. The fin 32 has a function of increasing a flow rate of a coolant at an arrangement position thereof and locally increasing cooling efficiency. A shape and a size of the fin 32 are appropriately determined in accordance with a cooling state required at the arrangement position. The fin 32 may be formed of the same material as the cooling plate 30, or may also be formed of a material different from the cooling plate 30. A configuration that the fin 32 is not provided is also applicable.

The bonding sheet 40 is a sheet having adhesion properties and made of resin such as thermosetting epoxy resin, for example. Bonding the electrostatic chuck 20 and the cooling plate 30 using the bonding sheet 40 is implemented by heat pressure bonding of pressurizing a laminated body in which the bonding sheet 40 is sandwiched between the electrostatic chuck 20 and the cooling plate 30 while heating the laminated body at a predetermined temperature. A thickness of the bonding sheet 40 is preferably 100 μm to 300 μm at least before bonding.

The wafer mount 10 further includes a first power supply part 50 supplying power to the ESC electrode 21 and a second power supply part 60 supplying power to the heater electrode 22.

The first power supply part 50 is provided along a direction in which the electrostatic chuck 20 and the cooling plate 30 are stacked, and includes a power supply terminal 51, an insulating member (sleeve) 52 surrounding the power supply terminal 51, and a connection part 53 provided to one end part of the power supply terminal 51 and connected to the ESC electrode 21. The first power supply part 50 is inserted and fitted to a through hole 33, and is exposed outside on a side of the other end part. The power supply terminal 51 is electrically connected to an ESC power source 70 arranged outside on the side of the other end part.

In the wafer mount 10, when the DC voltage is applied to the ESC electrode 21 by the ESC power source 70 via the power supply terminal 51 and the connection part 53 while the wafer is disposed on the mounting surface 20a of the electrostatic chuck 20, the wafer is electrostatically attracted to the mounting surface 20a.

The second power supply part 60 includes a power supply terminal 61, an insulating member (sleeve) 62 surrounding the power supply terminal 61, and a connection part 63 provided to one end part of the power supply terminal 61 and connected to the heater electrode 22. The second power supply part 60 is inserted and fitted to a through hole 34 in the cooling plate 30, and is exposed outside on a side of the other end part. The power supply terminal 61 is electrically connected to a heater power source 80 arranged outside on the side of the other end part.

In the wafer mount 10, when power conduction is performed on the heater electrode 22 by the heater power source 80 via the power supply terminal 61 and the connection part 63, the wafer mount 10 and further the wafer are heated.

Furthermore, a coolant entrance 35 communicating with the flow path 31 penetrates the cooling plate 30. Although FIG. 1 illustrates only one coolant entrance 35 for simplifying the illustration, the coolant entrance 35 is actually provided one by one to both end parts of the groove part constituting the flow path 31. Each coolant entrance 35 is connected to a chiller unit 90 circulating and supplying the coolant to the flow path 31.

In the wafer mount 10 having the above configuration, with the wafer disposed on the mounting surface 20a being fixed via electrostatic attraction by applying voltage to the ESC electrode 21, heating by power conduction on the heater electrode 22 and circulation supply of the coolant to the flow path 31 are performed in parallel, so that the heating and cooling are balanced, and therefore the wafer can be heated with a predetermined temperature distribution.

The wafer mount 10 can be manufactured by a procedure of preparing cooling plate 30 and the electrostatic chuck 20 into which the ESC electrode 21 and the heater electrode 22 are buried, bonding the electrostatic chuck 20 and the cooling plate 30 by the bonding sheet 40, and then burying the first power supply part 50 and the second power supply part 60, for example.

The electrostatic chuck 20 can be manufactured by hot-press sintering a green sheet laminated body formed by adhesively laminating a plurality of ceramics green sheets including a ceramics green sheet on which an electrode pattern for the ESC electrode 21 is formed by printing and a ceramics green sheet on which an electrode pattern for the heater electrode 22 is formed by printing, for example.

It is also applicable that embossing (uneven processing) is performed on the mounting surface 20a of the electrostatic chuck 20 after the hot-press sintering to provide a number of protrusions (projections).

The cooling plate 30 can be manufactured by cutting a bulk metal, mold casting, or the other casting method, for example.

### <Detailed Structure of Electrostatic Chuck>

Described hereinafter is a detailed structure of a bonding part between the electrostatic chuck 20 made of ceramics and the bonding sheet 40 made of resin included in the wafer mount 10 according to the present embodiment.

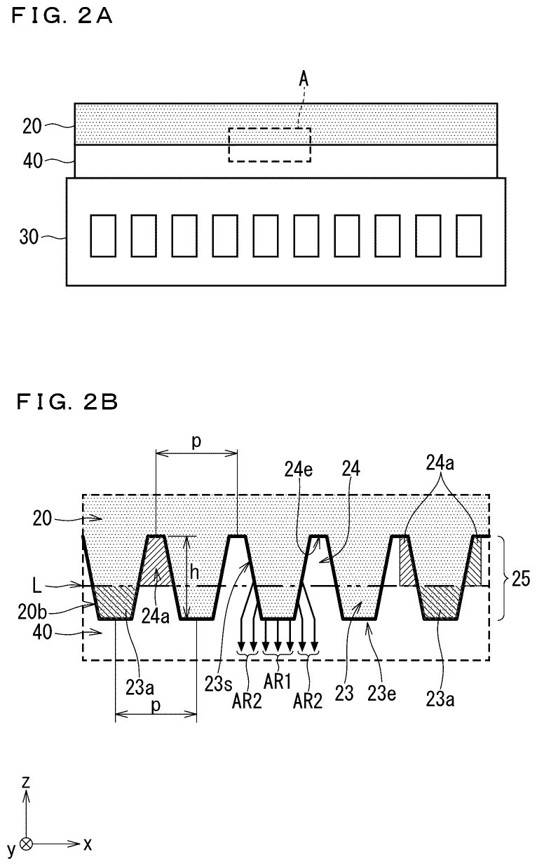

FIG. 2A and FIG. 2B are schematic views for explaining the detailed structure of the bonding part between the electrostatic chuck 20 and the bonding sheet 40. FIG. 2A is a schematic cross-sectional view of the wafer mount 10, and FIG. 2B is a schematic enlarged cross-sectional view of a part A illustrated in FIG. 2A. A dimension of each part illustrated in FIG. 2A and FIG. 2B is different from that of an actual structure, and particularly, a thickness of the bonding sheet 40 is exaggerated.

In FIG. 2A or FIG. 1, an interface between the electrostatic chuck 20 and the bonding sheet 40 is flatly illustrated. However, this is merely a simplified illustration. In the electrostatic chuck 20 according to the present embodiment, a bonding surface 20b as an interface with the bonding sheet 40 has a minute uneven structure 25 that a large number of protrusions 23 and recesses 24 are alternately and periodically provided.

More specifically, each protrusion 23 is located away from each other at a predetermined pitch p in a first direction as a direction in a plane end extends with a predetermined length in a second direction perpendicular to the first direction in the plane.

Applied in FIG. 2A, FIG. 2B, and the subsequent diagrams is a right-handed xyz coordinate system that the first direction is an x axis direction, the second direction is a x axis direction, and a direction perpendicular to these x axis and y axis is a z axis direction. The configuration of the wafer mount 10 is described based on a premise of a case where the cooling plate 30, the bonding sheet 40, and the electrostatic chuck 20 are stacked in this order in a z axis positive direction, that is to say, vertically upward, and a planar surface (xy planar surface) including an x axis and a y axis is parallel to a horizontal surface.

In such a case, each protrusion 23 protrudes in a z axis negative direction, is located away from each other at a predetermined pitch p in the x axis direction, and linearly extends with a predetermined length in a y axis direction perpendicular to the x axis direction in a horizontal plane.

The recess 24 is a portion between the protrusions 23 adjacent to each other in the x axis direction constitute. As in the protrusions 23, each recess 24 is also located away from each other at the predetermined pitch p in the x axis direction, and linearly extends with a predetermined length in the y axis direction perpendicular to the x axis direction in the horizontal plane.

Such an uneven structure 25 included in the electrostatic chuck 20 is also referred to as a rib structure hereinafter. In a case illustrated in FIG. 2B, a height of a distal end surface (a lowermost end surface in FIG. 2B) 23e of the individual protrusion 23 constituting the uneven structure (rib structure) 25 closest to the cooling plate 30 is uniform, and a height of a bottom surface (an uppermost end surface in FIG. 2B) 24e of the individual recess 24 farthest away from the cooling plate 30 is also uniform. In the case illustrated in FIG. 2B, the protrusion 23 has a trapezoidal shape in a cross-sectional view, and a side surface part 23s thereof is an inclined surface. However, this configuration is not necessary, but the protrusion 23 may have a rectangular shape in a cross-sectional view.

When the electrostatic chuck 20 having such an uneven structure 25 in the interface is bonded to the cooling plate 30 by the bonding sheet 40 made of resin and thus having elasticity, the protrusion 23 enters the bonding sheet 40 and the bonding sheet 40 enters the recess 24 while being deformed. Accordingly, the recess 24 is completely filled with the bonding sheet 40. Bonding of the electrostatic chuck 20 and the cooling plate 30 by the bonding sheet 40 can be implemented by heat pressure bonding of pressurizing a laminated body thereof while heating the laminated body at a predetermined temperature.

A cross section of the uneven structure 25 illustrated in FIG. 2B necessarily includes an uneven reference line L satisfying a relationship described hereinafter. That is to say, the cross section thereof necessarily includes the uneven reference line L in which a cross-sectional area of a part 23a below (a negative side in the z axis direction) the uneven reference line L in one protrusion 23 and a cross-sectional area of a part 24a above (a positive side in the z axis direction) the uneven reference line L in one recess 24 adjacent to the one protrusion 23 are equal to each other. In consideration of symmetry, the part 24a is also considered parts of the recesses 24, divided into left and right halves as viewed in the diagram, located adjacent to the protrusion 23 on both sides in the horizontal direction and located above (the positive side in the z axis direction) the uneven reference line L.

The uneven reference line L constitutes a part of an uneven reference surface in parallel to an XY plane including the uneven reference line L. The uneven reference surface is a surface in which a volume of the part 23a below (the negative side in the z axis direction) the uneven reference line L in one protrusion 23 and a volume of a part 24a above the uneven reference line L the recess 24 adjacent to the protrusion 23 are equal to each other.

In other words, the uneven structure 25 is provided to include such an uneven reference line L. To clarify, a height position of the uneven reference line L is not necessarily the same as an intermediate position of a distance (hereinafter referred to as an unevenness heigh) h between the distal end surface 23e of the protrusion and the bottom surface 24e of the recess 24.

The uneven reference line L is a line indicating a height corresponding to a lower surface of the electrostatic chuck 20 in virtually uniforming and flattening the uneven structure 25. When the protrusion 23 and the recess 24 are formed based on the preset uneven reference line L, resin of the bonding sheet 40 pressed away by entry of the protrusion 23 below the uneven reference line L enters a part above the uneven reference line L of the recesses 24 adjacent to each other with no excess and shortage. That is to say, entry of the protrusion 23 into the bonding sheet 40 and entry of the bonding sheet 40 into the recess 24 are balanced above and below the uneven reference line L.

Thus, in a macro view, bonding of the electrostatic chuck 20 having the uneven structure 25 and the cooling plate 30 by the bonding sheet 40 is substantially equivalent to bonding of the electrostatic chuck 20 having the bonding surface as a flat surface corresponding to the uneven reference line L with no uneven structure 25 and the cooling plate 30 by the bonding sheet 40.

In the meanwhile, in the wafer mount 10 according to the present embodiment, the contact area between the electrostatic chuck 20 and the bonding sheet 40 increases compared with the case where the flat surface with no uneven structure 25 serves as the bonding surface. Thus, bonding strength of the electrostatic chuck 20 is increased.

When the electrostatic chuck 20 generates heat via power supply to the heater electrode 22 such as a case where the wafer disposed on the mounting surface 20a is heated, the heat is transmitted from the electrostatic chuck 20 to the cooling plate 30 via the bonding sheet 40. In the case that the uneven structure 25 illustrated in FIG. 2B is adopted, heat transmission via the protrusion 23 (particularly, near the distal end surface 23e) is more dominant than heat transmission via a part of the bonding sheet 40 entering the recess 24 (particularly, near the bottom part 24e) by reason that ceramics constituting the electrostatic chuck 20 has a higher heat conductivity rate than resin constituting the bonding sheet 40. This is because not only heat transmission in the distal end surface 23e shown by an arrow AR1 but also heat transmission shown by an arrow AR2 from the side surface part 23s near the distal end surface 23e easily occur. For example, a heat conductivity rate of Al₂O₃ (alumina) exemplified as a ceramics material constituting the electrostatic chuck 20 is 35 W/m. K. In contrast, a heat conductivity rate of thermosetting epoxy resin exemplified as a resin material constituting the bonding sheet 40 is 0.2 W/m. K.

As a result, heat transmission occurs more efficiently in the electrostatic chuck 20 having the uneven structure 25 along a certain uneven reference line L than the electrostatic chuck 20 including merely the flat bonding surface in the position corresponding to the uneven reference line L.

Furthermore, if the thickness variation of the bonding sheet 40 is ignored, the distance between the cooling plate 30 and the distal end surface 23e of the protrusion 23 is constant in any position in the range where the height of the distal end surface 23e of the protrusion 23, which dominates heat transmission as described above, is uniform. Thus, as a whole of the range, a uniform state of heat transmission from the electrostatic chuck 20 to the cooling plate 30 via the bonding sheet 40 is achieved.

The fact that the electrostatic chuck 20 having the uneven structure 25 is excellent in heat conductivity compared with the electrostatic chuck 20 with no the uneven structure 25 also means that, as long as a condition of power conduction heating using the heater electrode 22 is the same, heat transmission from the wafer occurs more easily and the wafer is cooled more easily in a case of heating by power conduction on the heater electrode 22 in the wafer mount 10 using the former configuration than in a case of similar heating by power conduction in the wafer mount 10 using the latter configuration. In consideration of this point, when the wafer is heated by power conduction with the former configuration to the same temperature as the case with the latter configuration, it is sufficient that heater power from the heater power source 80 is increased when the wafer mount 10 is used or the bonding sheet 40 having a large thickness is previously used. In such a case, the wafer can be heated in the manner similar to the case of the electrostatic chuck 20 with no uneven structure 25 while heat transmission is uniformed.

The pitch p of the protrusion 23 is preferably equal to or larger than 100 μm and equal to or smaller than 300 μm. In a case of a rib structure 25 illustrated in FIG. 2B, the recess 24 also has the same pitch p. When the pitch p of the protrusion 23 is smaller than 100 μm, an accuracy of processing including formation of the recess 24 is not easily ensured, and the desired uneven structure 25 is not easily obtained, which is not preferable. When the pitch p of the protrusion 23 is larger than 300 μm, the resin constituting the bonding sheet 40 needs to be significantly moved (displaced or deformed) to make the bonding sheet 40 enter the recess 24 in bonding, and residual stress remains after bonding, which is not preferable.

More preferably, the pitch p of the protrusion 23 is equal to or larger than 150 μm. In such a case, the desired uneven structure 25 can be formed relatively easily and reliably, and an effect of efficiency of heat transmission can also be favorably obtained.

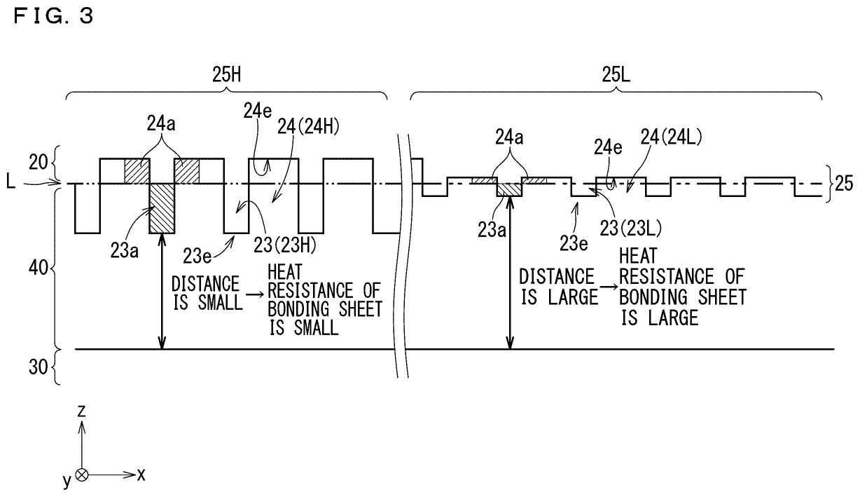

Shapes of the protrusion 23 and the recess 24 corresponding to a certain uneven reference line L is not limited to one pattern. FIG. 3 is a diagram exemplifying uneven structures 25 (25H and 25L) with two patterns in which the shapes of the protrusion 23 and the recess 24 are different from each other, although the uneven reference line L is common thereto.

In the uneven structure 25H illustrated on a left side of FIG. 3, a cross section of the protrusion 23 (23H) has a vertically long shape as viewed in the diagram with a narrow width in a horizontal direction (x axis direction). In the meanwhile, a cross section of the recess 24 (24H) has a wider width than the protrusion 23 (23H) in the horizontal direction. Although a distance from the uneven reference line L to the distal end surface 23e of the protrusion 23 is larger than a distance from the uneven reference line L to the bottom surface 24e of the recess 24, a cross-sectional area of the part 23a below the uneven reference line L and a cross-sectional area of the part 24a above the uneven reference line L are equal to each other.

In the meanwhile, also in the uneven structure 25L illustrated on a right side in FIG. 3, the cross-sectional area of the part 23a below the uneven reference line L and the cross-sectional area of the part 24a above the uneven reference line L are equal to each other.

Comparing the uneven structure 25H with the uneven structure 25L, the uneven reference line L is common to each other, and the distance from the distal end surface 23e of the protrusion 23 to the cooling plate 30 is constant in the range of each structure. In the meanwhile, a distance from the uneven reference line L to the distal end surface 23e of the protrusion 23H in the uneven structure 25H is larger than a distance from the uneven reference line L to the distal end surface 23e of the protrusion 23L in the uneven structure 25L. Thus, a distance from the protrusion 23H to the cooling plate 30 is smaller than that from the protrusion 23L thereto.

Hereinafter, the uneven structure 25H in which the distal end surface 23e of the protrusion 23 is relatively away from the uneven reference line L is also referred to as a high rib structure (or an H rib) 25H, and the uneven structure 25L in which the distal end surface 23e of the convex part 23 is relatively close to the uneven reference line L is also referred to as a low rib structure (or an L rib) 25L. The high rib structure 25H and the low rib structure 25L illustrated in FIG. 3 are merely schematic examples. Thus, specific shapes are not limited thereto.

Such a difference of the uneven structure 25 is related to a magnitude of heat transmission from the electrostatic chuck 20 to the cooling plate 30 via the bonding sheet 40.

That is to say, the smaller the distance from the distal end surface 23e to the cooling plate 30, the larger heat resistance of the bonding sheet 40, and the larger a heat transmission amount thereof. In contrast, the larger the distance from the distal end surface 23e to the cooling plate 30, the higher heat resistance of the bonding sheet 40, and the smaller a heat transmission amount thereof. Thus, in the case illustrated in FIG. 3, heat transmission from the distal end surface 23e of the protrusion 23 is larger in the high rib structure 25H than in the low rib structure 25L illustrated on the right side. That is to say, when the condition of the power conduction heating using the heater electrode 22 is the same, a position having the high rib structure 25H is cooled more easily than a position having the low rib structure 25L.

In the present embodiment, a relationship between the distance from the distal end surface 23e of the protrusion 23 to the cooling plate 30 and the heat resistance of the bonding sheet 40 described above is used for correction of variation of a heat generation distribution in the mounting surface 20a of the electrostatic chuck 20. In principle, the distal end surface 23e of the protrusion 23 is brought closer to the cooling plate 30 in the uneven structure 25 provided to a side of an opposite surface in a position having a higher temperature than a certain reference temperature, and is brought farther away from the cooling plate 125 in a position having a lower temperature than the certain reference temperature, so that variation of a temperature (or a heat generation density) in the mounting surface 20a can be reduced (heat is uniformed in the mounting surface 20a) compared with a case where no correction is performed.

The correction is merely intended to reduce the temperature variation with respect to a certain reference temperature. An absolute adjustment of a temperature in a specific position in the mounting surface 20a to coincide with a reference temperature, for example, is performed by adjusting a heater power inputted to the heater power source 80 in using the wafer mount 10 or previously adjusting a thickness of the bonding sheet 40 to be used.

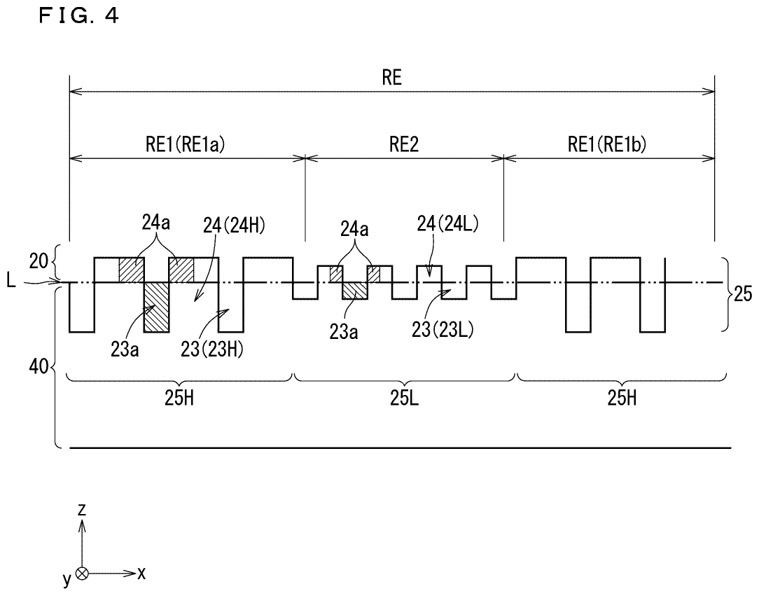

FIG. 4 is a diagram for explaining a variation correction of a temperature (or a heat generation density) performed in the present embodiment. In the present embodiment, the electrostatic chuck 20 is virtually sectioned in a plurality of unit region RE in a plan view, and a mixing ratio (a planar surface area ratio) between the high rib structure 25H and the low rib structure 25L in each unit region RE is differed in accordance with a temperature before correction; thus, the temperature (or the heat generation density) is corrected for each unit region RE. A region where the high rib structure 25H is provided in the unit region RE is referred to as a sub region RE1, and a region where the low rib structure 25L is provided is referred to as a sub region RE2.

More specifically, a correspondence relationship between a planar surface area ratio between the sub region RE1 and the sub region RE2 and a correction amount of a temperature (or a heat generation density) is previously and experimentally specified using a relationship that as the high rib structure 25H gets larger, temperature reduction occurs more easily, and as the low rib structure 25L gets larger, temperature reduction occurs more hardly. Then, an area ratio applied to the individual unit region RE is set based on an actual heat generation distribution, and the uneven structure 25 corresponding to the area ratio is provided to each unit region. A combination of the high rib structure 25H and the low rib structure 25L providing such a planar surface area ratio between the sub region RE1 and the sub region RE2 is also referred to as a rib pattern.

The high rib structure 25H and the low rib structure 25L are also referred to as a first unit structure and a second unit structure, respectively. In other words, one or plural types of unit structures are mixed at a predetermined ratio in the rib pattern. The protrusion 23H and the recess 24H of the high rib structure 25H are also referred to as the first protrusion and the first recess, respectively, and the protrusion 23L and the recess 24L of the low rib structure 25L are also referred to as the second protrusion and the second recess, respectively.

Exemplified in the case illustrated in FIG. 4 is a case where an area ratio between the sub region RE1 of the high rib structure 25H made up of two partial sub regions RE1a and RE1b and the sub region RE2 of the low rib structure 25L between two partial sub regions RE1a and RE1b is 2:1. The sub region RE2 may include the partial sub region, and the number of partial sub regions in the sub regions RE1 and RE2 is not particularly limited. The sub regions RE1 and RE2 are preferably provided in al least the unit region RE periodically.

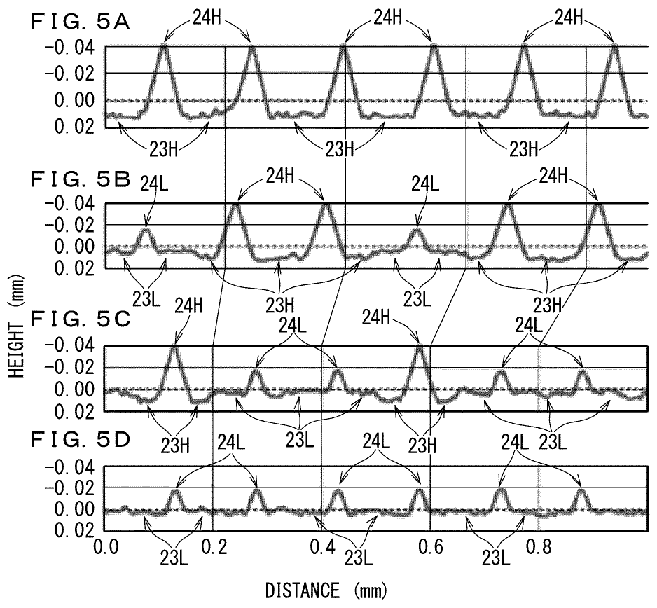

FIGS. 5A to 5D are diagrams illustrating an actually-measured cross-sectional shape profile of the electrostatic chuck 20 in a case where the high rib structure 25H with the pitch p of 150 μm and the unevenness height h of 50 μm and the low rib structure 25L with the pitch p of 150 μm and the unevenness height h of 20 μm are provided in the unit region RE having a planar surface size of 37.5 mm×37.5 mm so that a ratio therebetween are differed in four patterns. The reference temperature is set to 97.7° C.

FIG. 5A is a profile of a rib pattern in which only the high rib structure 25H is provided. It is experimentally confirmed that this rib pattern can achieve temperature correction of reducing a temperature difference by 1° C. from the reference temperature in the mounting surface 20a having a higher temperature than the reference temperature. This is caused by a configuration that when the protrusion 23H included in the high rib structure 25H enters the bonding sheet 40 in bonding, the distal end surface 23e of the protrusion 23H gets closer to the cooling plate 30 compared with a case where no correction is performed (a case where bonding is performed at the flat bonding surface). Thus, a heat transmission amount from the mounting surface 20a is increased.

In the meanwhile, FIG. 5D is a profile of a rib pattern in which only the low rib structure 25L is provided. It is experimentally confirmed that this rib pattern can achieve temperature correction of reducing a temperature difference by 1° C. from the reference temperature in the mounting surface 20a having a lower temperature than the reference temperature. This is caused by the fact that the protrusion 23L included in the low rib structure 25L also enters the bonding sheet 40 in bonding; in contrast, the distance from the distal end surface 23e of the protrusion 23L to the cooling plate 30 gets larger compared with a case where no correction is performed (a case where bonding is performed at the flat bonding surface). Thus, a heat transmission amount from the mounting surface 20a is reduced.

In the description hereinafter, the correction by the former rib pattern is also referred to as correction with a temperature correction amount of −1° C., and the correction by the latter rib pattern is also referred to as a correction with a temperature correction amount of +1° C.

Furthermore, FIG. 5B is a profile of a rib pattern in which the high rib structure 25H and the low rib structure 25L are provided at a ratio of 2:1. In the meanwhile, FIG. 5C is a profile of a rib pattern in which the high rib structure 25H and the low rib structure 25L are provided at a ratio of 1:2. When these rib patterns are adopted, it is also confirmed that the temperature correction amounts in the mounting surface 20a are −0.33° C. and +0.33° C., respectively. This indicates that the temperature correction amount in a case where the rib pattern including both the high rib structure 25H and the low rib structure 25L is adopted takes an intermediate value of the temperature correction amount of the rib pattern in which only one of these structures is provided.

In this manner, when the rib pattern in the individual unit region RE in the mounting surface 20a is differed in accordance with the temperature before the correction, the electrostatic chuck 20 with the improved heat uniformity compared with the case where no correction is performed can be obtained.

### <Specific Example of Correction of Temperature Variation>

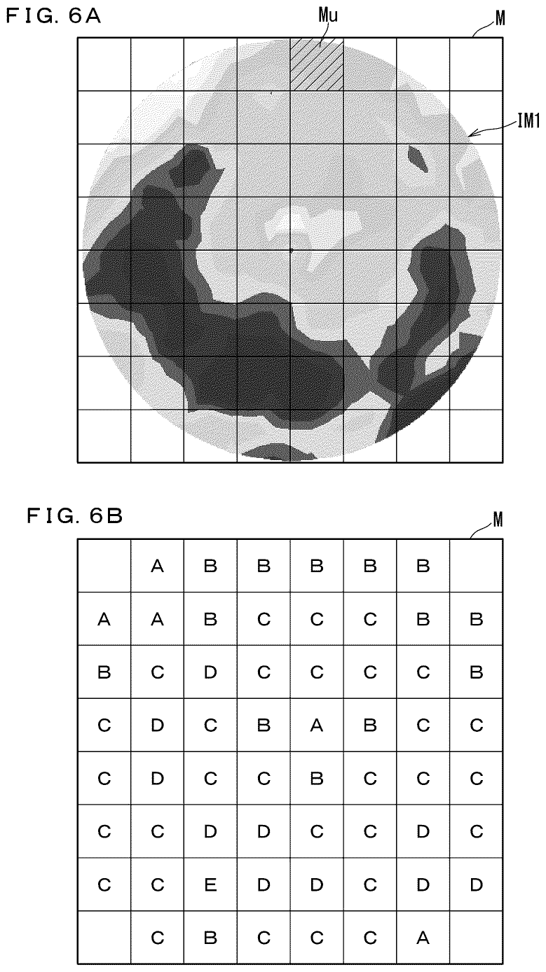

Described next is a specific example of a temperature variation correction in the mounting surface 20a by difference of the rib pattern, in other words, by difference of the area ratio between the sub region RE1 and the sub region RE2. FIG. 6A and FIG. 6B are diagrams for each explaining specific contents of the temperature variation correction.

In performing the variation correction, originally, it should be that the wafer mount 10 is formed once using the electrostatic chuck 20 before correction with no uneven structure 25 (no uneven electrostatic chuck hereinafter), the obtained electrostatic chuck 20 is heated through power conduction on the heater electrode 22, and thereafter, the uneven structure 25 is provided to the electrostatic chuck 20 based on the temperature distribution of the mounting surface 20a obtained as a result of heating. However, in this case, the electrostatic chuck 20 with no the uneven structure 25 once bonded to the cooling plate 30 by the bonding sheet 40 needs to be separated to provide the uneven structure 25. However, it is not easy to separate the electrostatic chuck 20 again, and moreover, there is a possibility that a bonding state is changed if the uneven structure 25 is formed in the electrostatic chuck 20 and the electrostatic chuck 20 is bonded again. Thus, such a configuration is not necessarily realistic.

In the meanwhile, when a large number of no uneven electrostatic chucks are manufactured in one manufacturing condition, for example, there is a high probability that a temperature distribution in each of no uneven electrostatic chucks is substantially the same. Thus, in the present embodiment, based on the above premise, the temperature distribution of the mounting surface 20a such as illustrated in FIG. 6A is measured in the wafer mount 10 made up using one of the large number of no uneven electrostatic chucks, and, with regarding a result thereof as the temperature distribution before correction for the other electrostatic chuck 20 manufactured in the same condition, the correction of the temperature variation in the other electrostatic chuck 20 is performed as part of a preparation processing before bonding. That is to say, as for the individual unit region RE in the electrostatic chuck 20 whose manufacturing lot is the same as the electrostatic chuck 20 on which the temperature distribution measurement has been performed, the uneven structure 25 is provided with a common rib pattern based on the temperature distribution before the correction.

In such a case, the no uneven electrostatic chuck 20 providing the temperature distribution before correction of the mounting surface 20a is referred to as the reference electrostatic chuck 20, and the electrostatic chuck 20 to which the temperature variation correction is performed by providing the uneven structure 25 based on the temperature distribution before correction is referred to as the correction target electrostatic chuck 20.

FIG. 6A is a diagram illustrating a temperature distribution image (thermography image) IM1 for the mounting surface 20a of the reference electrostatic chuck 20 when power conduction is performed on the heater electrode 22 of the reference electrostatic chuck 20 in the wafer mount 10, wherein a ceramics member of the electrostatic chuck 20 is alumina (Al₂O₃) and the bonding sheet 40 is made of thermoplastic epoxy resin. It is indicated in the temperature distribution image IM1 that a position with a color closer to white relatively has a higher temperature, and a position with a color closer to black relatively has a lower temperature. A high temperature region is located on upper right and left sides, and a low temperature region extends over a wide range except for an area near a center in a lower half of the temperature distribution image IM1. A difference between a highest temperature and a lowest temperature is 3.1° C.

In FIG. 6A, a mesh M having a square shape with each side of 37.5 mm is virtually overlapped with such a temperature distribution image IM1. The mesh M is made up of 64 (8×8) unit meshes Mu in total each having a square shape. Each unit mesh Mu corresponds to the unit region RE described above, and the temperature correction amount in the unit region RE corresponding to the unit mesh Mu in the correction target electrostatic chuck 20 is determined based on the temperature distribution in the individual unit mesh Mu in the temperature distribution image IM1. The uneven structure 25 (the rib pattern) corresponding to the determined temperature correction amount is formed for each unit region RE in the bonding surface 20b of the correction target electrostatic chuck 20.

In the present correction example, a temperature is corrected in the individual unit region RE by applying any one of five rib patterns A to E shown in Table 1. At that time, the correction is performed so that an intermediate temperature of the highest temperature and the lowest temperature described above is set to a reference temperature. In Table 1, a condition where an area ratio of an L rib or an H rib is 0 indicates that only the H rib (the high rib structure 25H) or the L rib (the low rib structure 25L) is formed.

TABLE 1

| | | Rib pattern | | | | |
|---|---|---|---|---|---|---|
| | | A | B | C | D | E |
| Rib area | H rib | 6 | 4 | 3 | 2 | 0 |
| ratio | L rib | 0 | 2 | 3 | 4 | 6 |

| | | | | | |
|---|---|---|---|---|---|
| Temperature adjustment | −1.0° | −0.33° | ±0° | +0.33° | +1.0° |
| amount | C. | C. | C. | C. | C. |

Table 1 indicates, for example, that the rib pattern A made up of only the high rib structure 25H is applied to the unit region RE where it is determined that the temperature should be reduced by 1° C. in the mounting surface 20a compared with the temperature before correction in accordance with the temperature distribution in the unit mesh Mu. In the similar manner, the rib pattern B made up of the high rib structure 25H and the low rib structure 25L at a ratio of 4:2 (=2:1) is applied to the unit region RE where it is determined that the temperature should be reduced by 0.33° C. in the mounting surface 20a compared with the temperature before correction, the rib pattern C made up of the high rib structure 25H and the low rib structure 25L at a ratio of 3:3 (=1:1) is applied to the unit region RE where it is determined that the temperature is close to the reference temperature and the temperature before correction should be kept, the rib pattern D made up of the high rib structure 25H and the low rib structure 25L at a ratio of 2:4 (=1:2) is applied to the unit region RE where it is determined that the temperature should be increased by 0.33° C. in the mounting surface 20a compared with the temperature before correction, and the rib pattern E made up of only the low rib structure 25L is applied to the unit region RE where it is determined that the temperature should be increased by 1° C. in the mounting surface 20a compared with the temperature before correction. The setting of the rib pattern is not limited thereto indicated by Table 1, and the rib pattern may be appropriately set in accordance with the obtained temperature distribution image.

FIG. 6B is a diagram illustrating the rib patterns applied to the unit regions RE each corresponding to the individual unit mesh Mu, which are set based on the temperature distribution image IM1, and are shown to correspond to the mesh Min FIG. 6A. The uneven structure 25 is provided to each unit region RE of the correction target electrostatic chuck 20 based on the rib pattern.

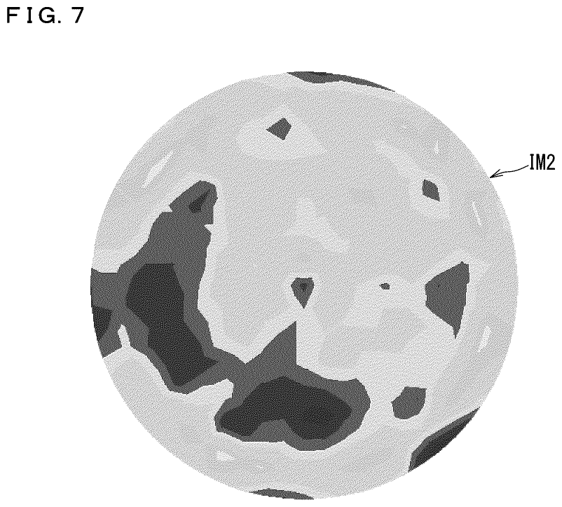

FIG. 7 is a diagram illustrating a temperature distribution image IM2 for the mounting surface 20a of the wafer mount 10 made up using the correction target electrostatic chuck 20 whose manufacturing lot is the same as the reference electrostatic chuck 20 for which the temperature distribution image IM1 in FIG. 6A is obtained. A temperature scale by contrast of color is unified with that of the temperature distribution image IM1.

Comparing the temperature distribution image IM2 with the temperature distribution image IM1, a significant high temperature region is resolved, and a low temperature region is also reduced, in the temperature distribution image IM2. A difference between a highest temperature and a lowest temperature is 2.2° C.

The result indicates that correction of temperature variation according to the present embodiment is an effective means.

### <Method of Forming Uneven Structure>

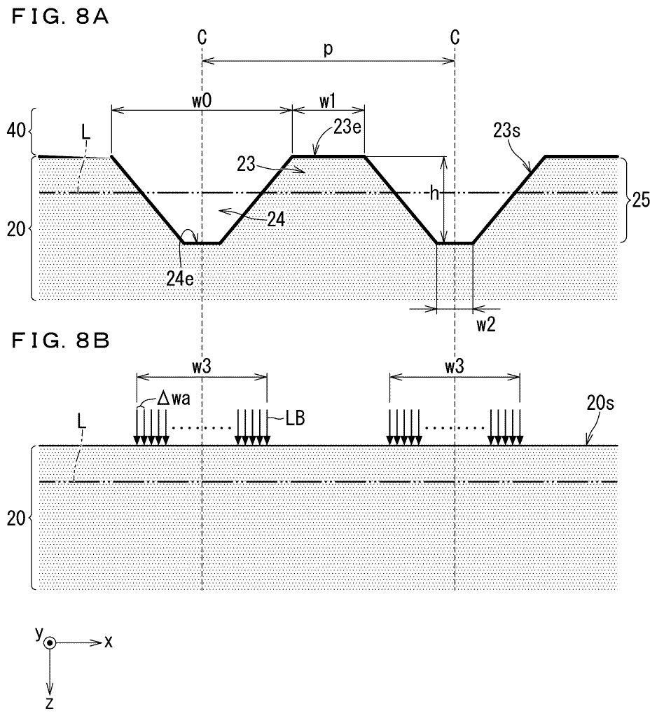

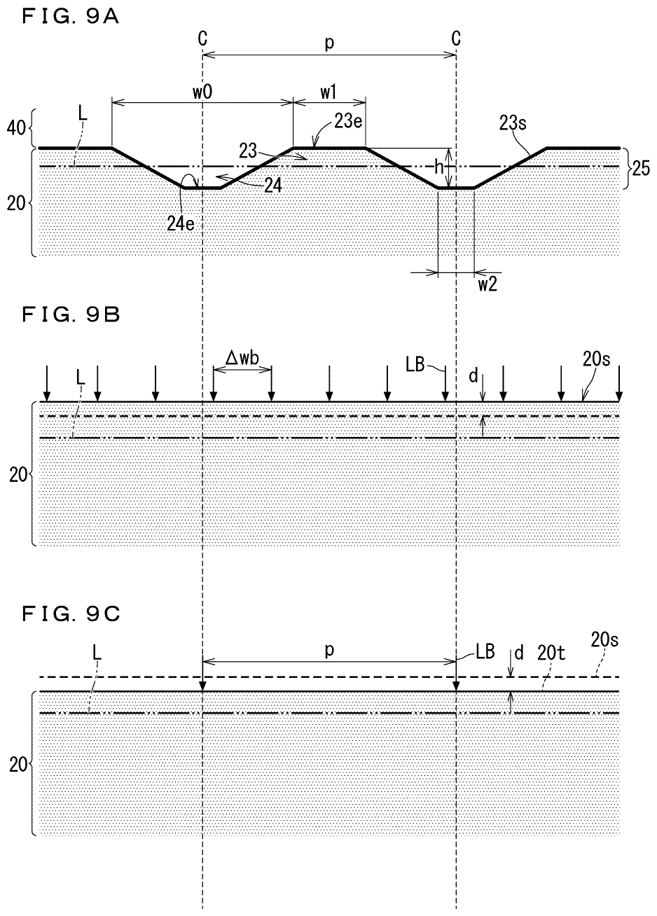

One aspect of a method of forming the uneven structure 25 as a preparation process before bonding is described next. Described specifically is an aspect of forming a rib structure that the protrusion 23 and the recess 24 have a trapezoidal shape in a cross-sectional view in laser processing. FIG. 8A and FIG. 8B are diagrams each illustrating formation of the high rib structure 25H, and FIG. 9A to FIG. 9C are diagrams each illustrating formation of the low rib structure 25L. FIG. 8A, FIG. 8B, and FIG. 9A to FIG. 9C illustrate the electrostatic chuck 20 vertically inverted with respect to FIG. 2A and FIG. 2B, for example.

In all of the rib structures, the recess 24 is formed in common in the position irradiated with laser light LB by repetitive irradiation of a processing target surface (a surface on a side opposite to the mounting surface 20a) 20s in the electrostatic chuck 20 before processing (before correction) with the laser light LB along the y axis direction. However, a manner of a specific irradiation is different from each other.

Now, in the uneven structure 25 (the high rib structure 25H or the low rib structure 25L) at the pitch p to be formed, let a width of the distal end surface 23e of the protrusion 23 be w1, a width of the bottom surface 24e of the recess 24 be w2, an unevenness height (a distance from the distal end surface 23e of the protrusion 23 to the bottom surface 24e of the recess 24) be h, and a maximum opening width of the recess 24 (a width at the same height with the distal end surface 23e of the protrusion 23) be w0, as illustrated in FIG. 8A and FIG. 9A. The recess 24 is formed so that a zx cross section perpendicular to the y axis direction as an extension direction thereof is symmetric with respect to a center axis C extending in the vertical direction (z axis direction).

In such a case, although a specific numeral value is different, all of the high rib structure 25H and the low rib structure 25L illustrated in FIG. 8A and FIG. 9A have a structure that the protrusion 23 having the distal end surface 23e with the width of w1 and the height of h and extending in the y axis direction and the recess 24 having the bottom surface 24e with the width w2, having a maximum opening width of w0, and extending in the y axis direction in the similar manner are alternately located adjacent to each other in the x axis direction.

From a viewpoint of favorably ensuring heat conductivity from the electrostatic chuck 20 to the bonding sheet 40, the width w1 of the distal end surface 23e of the protrusion 23 is preferably equal to or larger than 40 μm, and also from a viewpoint of reducing influence of variation in processing, the width w1 of the distal end surface 23e of the protrusion 23 is preferably equal to or larger than 40 μm. When an inclination of the side surface part 23s of the protrusion 23 with respect to a horizontal surface (an xy planar surface) is equal to or smaller than 45 degrees and the width w2 of the bottom surface 24e of the recess 24 is equal to or larger than 10 μm, adhesion properties of the bonding sheet 40 are ensured more sufficiently.

When the high rib structure 25H is formed, it is sufficient that positions located away from each other at a predetermined irradiation pitch Δwa in the x axis direction are sequentially irradiated with the laser light LB in a range of a predetermined width w3 along the x axis direction in the processing target surface (the surface on the side opposite to the mounting surface 20a) 20s of the electrostatic chuck 20 before processing (before correction) as illustrated in FIG. 8B. The width w3 is set so that a center position thereof in the x axis direction is located in a position of the center axis C of the recess 24 to be finally formed. When the protrusion 23 and the recess 24 having a trapezoidal shape in a cross-sectional view are provided as illustrated in FIG. 8A, the width w3 may be smaller than the maximum opening width w0 of the recess 24 to be formed. Irradiation with the laser light LB may be repeated a predetermined number of times.

For example, in the case that the high rib structure 25H having the pitch p of 150 μm, the distal end surface 23e of the protrusion 23 with the width w1 of 40 μm, the bottom surface 24e of the recess 24 with the width w2 of 10 μm, the recess 24 with the maximum opening width w0 of 140 μm, the unevenness height h of 45 μm, and the distance from the distal end surface 23e of the protrusion 23 to the uneven reference line L of 15 μm is formed using the laser light LB having an output of 20 W, a wavelength 1030 nm, and a frequency 200 kHz, it is sufficient that irradiation with the laser light LB with the width w3 of 29 μm and the irradiation pitch Δwa of 1 μm (that is to say, irradiation at 30 positions) is performed around the position of the center axis C of the recess 24 to be formed three times.

In the meanwhile, when the low rib structure 25L is formed, firstly, positions located away from each other at a predetermined irradiation pitch Δwb in the x axis direction are sequentially irradiated with the laser light LB in a whole formation target range of the low rib structure 25L in the processing target surface (the surface on the side opposite to the mounting surface 20a) 20s of the electrostatic chuck 20 before processing (before correction) as illustrated in FIG. 9B. Accordingly, the ceramics member constituting the electrostatic chuck 20 is removed by a predetermined depth d on a side of the processing target surface 20s. The irradiation with the laser light LB described above is referred to as a primary irradiation. The primary irradiation may be repeated a predetermined number of times.

Subsequently, as illustrated in FIG. 9C, positions located away from each other at the pitch p are sequentially irradiated with the laser light LB in a surface 20t newly formed by the above removal. The irradiation position in the x axis direction is set to be a position serving as the center axis C of the recess 24 to be finally formed. The irradiation with the laser light LB described above is referred to as a secondary irradiation. The secondary irradiation may be repeated a predetermined number of times.

For example, in the case that the low rib structure 25L having the pitch p of 150 μm, the distal end surface 23e of the protrusion 23 with the width w1 of 40 μm, the bottom surface 24e of the recess 24 with the width w2 of 10 μm, the recess 24 with the maximum opening width w0 of 140 μm, the unevenness height h of 45 μm, and the distance from the distal end surface 23e of the protrusion 23 to the uneven reference line L of 15 μm is formed using the laser light LB having an output of 20 W, a wavelength 1030 nm, and a frequency 200 kHz, it is sufficient that the primary irradiation with the laser light LB at the irradiation pitch Δwb of 15 μm is performed once and then the secondary irradiation at the pitch of 150 μm is performed 10 times.

In FIG. 8A, FIG. 8B, and FIG. 9A to FIG. 9C, the side surface part 23s of the protrusion 23 has a linear shape in a cross-sectional view for simplifying the illustration, but may have a step-like shape or a curved shape in some cases depending on a processing condition.

As described above, while the temperature variation is corrected for each unit region RE, a scanning distance of the laser light LB (a linear distance which can be processed by one continuous irradiation) in a known laser light irradiation apparatus capable of executing accurate irradiation with the laser light LB at a pitch of several micrometers to several tens of micrometers is approximately 70 mm at most. Thus, a size of the unit region RE is preferably equal to or smaller than 70 mm at least in a scanning direction (the y axis direction).

Since the rib pattern in each unit region RE is normally different in correcting the temperature variation, a combination of formation of the high rib structure 25H and the low rib structure 25L by irradiation with the laser light LB illustrated in FIG. 8A, FIG. 8B, and FIG. 9A to FIG. 9C also corresponds to the rib pattern applied to the individual unit region RE. Thus, the high rib structure 25H and the low rib structure 25L are provided to the plurality of unit regions RE. In forming a desired rib pattern in each unit region RE, applicable is an aspect that all of the high rib structure 25H and the low rib structure 25L are formed over the whole processing target surface 20s, or, an aspect that the high rib structure 25H and the low rib structure 25L are sequentially formed in each individual unit region RE in accordance with the applied rib pattern.

### <Handling of Thickness Variation of Bonding Sheet>

As illustrated in FIG. 2B, the uneven structure 25 is provided in the wafer mount 10 according to the present embodiment, so that uniformity of heat transmission from the electrostatic chuck 20 to the cooling plate 30 via the bonding sheet 40 is achieved at the positions where the height of the distal end surface 23e of the protrusion 23 is the same as each other. Furthermore, as illustrated in FIG. 3 and FIG. 4, the temperature variation in the mounting surface 20a of the electrostatic chuck 20 is corrected for each unit region RE based on the rib pattern indicated by Table 1, for example, utilizing the fact that the magnitude of heat transmission is different in accordance with the distance from the distal end surface 23e of the protrusion 23 to the cooling plate 30.

Such a correction effect is obtained as intended originally in a case where there is substantially no thickness variation in the bonding sheet 40 before bonding or a case where the thickness variation can be substantially ignored. For example, the balance between entry of the protrusion 23 into the bonding sheet 40 and entry of the bonding sheet 40 into the recess 24 above and below the uneven reference line L as illustrated in FIG. 4 is based on the premise that the thickness of the bonding sheet 40 for bonding is uniform.

However, there is a case where the actual bonding sheet 40 locally or wholly includes the thickness variation (a value of deviation from a regulated thickness), which is approximately 2 μm at maximum when a target thickness is 200 μm, for example.

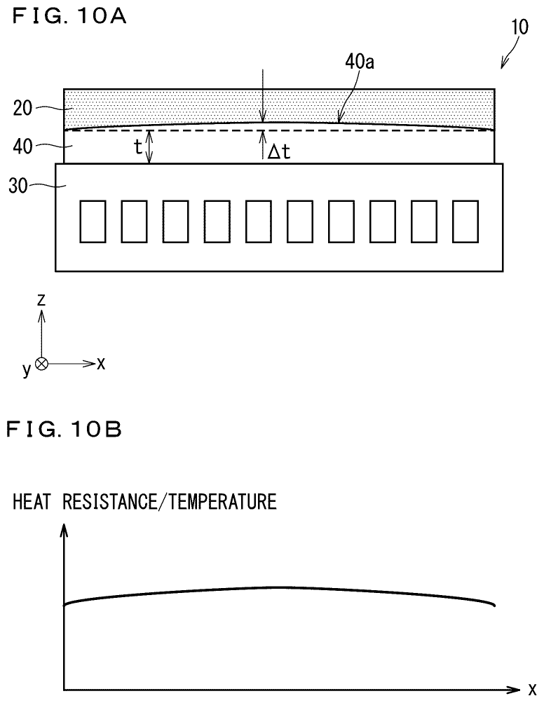

FIG. 10A and FIG. 10B are diagrams each schematically illustrating the wafer mount 10 with the thickness variation in the bonding sheet 40.

More specifically, FIG. 10A illustrates the wafer mount 10 in which the electrostatic chuck 20 and the cooling plate 30 are bonded by the bonding sheet 40 having an upper surface 40a, as a bonding surface bonded to the electrostatic chuck 20, with an upward protruding shape. It is premised that the thickness is increased by Δt at maximum with respect to a reference thickness t in the bonding sheet 40. In the present embodiment, the reference thickness t does not indicate a thickness which the bonding sheet 40 should originally has (a thickness assumed in designing the wafer mount 10) but indicates a smallest thickness. Thus, the thickness variation of the bonding sheet 40 in the present embodiment corresponds to a position having a relatively large thickness compared with the other position. It is also premised that carving processing corresponding to the shape of the upper surface 40a of the bonding sheet is performed to ensure flatness of the mounting surface 20a of the electrostatic chuck 20.

FIG. 10B illustrates a schematic profile of heat resistance in such a bonding sheet 40 in the x axis direction. FIG. 10B also corresponds to a profile of a temperature distribution in the mounting surface 20a in a case where heating by the heater electrode 22 is uniformly performed.

In a position where the bonding sheet 40 has a larger thickness, heat resistance is higher, and therefore, heat transmission from the electrostatic chuck 20 to the cooling plate 30 becomes smaller. That is to say, in the configuration illustrated in FIG. 10A, a difference of thickness of the bonding sheet 40 is dominant in heat transmission from the electrostatic chuck 20 to the cooling plate 30, and has influence on heat uniformity.

FIG. 10A exemplifies a case where one protrusion is located over the whole bonding sheet 40 for simplifying the illustration. But actually, there may be a case that one or a plurality of local thickness variations are located and carving processing dealing with the thickness variation is performed on the electrostatic chuck 20. Also in such a case, it is similar that the thickness variation directly has influence on heat transmission from the electrostatic chuck 20 to the cooling plate 30.

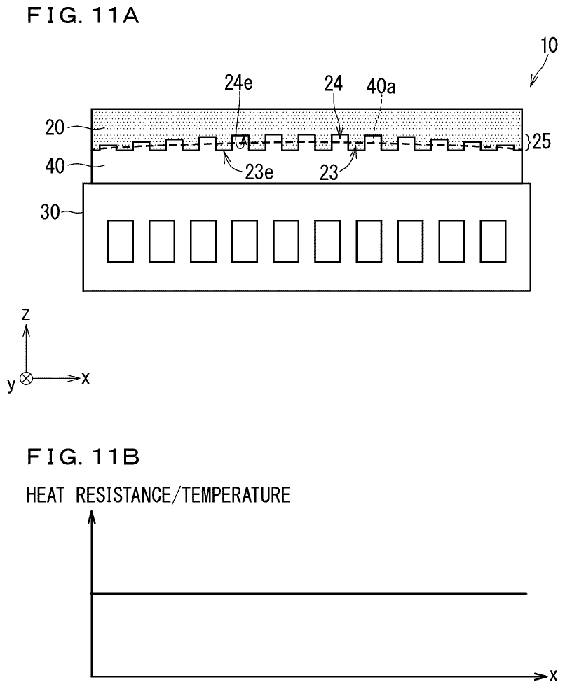

In the meanwhile, FIG. 11A and FIG. 11B are diagrams schematically illustrating the wafer mount 10 in which the uneven structure 25 dealing with the thickness variation of the bonding sheet 40 is provided to the electrostatic chuck 20.

More specifically, FIG. 11A illustrates the wafer mount 10 in which the electrostatic chuck 20 having the uneven structure 25 and the cooling plate 30 are bonded by the bonding sheet 40 having the same thickness variation as that in FIG. 10A. FIG. 11A illustrates a position of the upper surface 40a in FIG. 10A indicating the surface shape of the bonding sheet 40 before bonding by a broken line.

In the uneven structure 25 provided to the electrostatic chuck 20 illustrated in FIG. 11A, the height of the distal end surface 23e of the protrusion 23 is uniform in the manner similar to that illustrated in FIG. 3. On the other hand, the height of the bottom surface 24e of the recess 24 is differed depending on positions. More specifically, a degree of unevenness is small in a position where the thickness variation is small, and is large in a position where the thickness variation is large. As a result, the uneven structure 25 extends along the position of the upper surface 40a as a whole.

In such a case, although the uneven reference line L over the whole electrostatic chuck 20 cannot be considered, it can also be deemed that entry of the protrusion 23 into the bonding sheet 40 and entry of the bonding sheet 40 into the recess 24 above and below the upper surface 40a are locally and substantially balanced.

FIG. 11B illustrates a schematic profile of heat resistance in the bonding sheet 40 in the x axis direction in a case where bonding is performed in accordance with the aspect illustrated in FIG. 11A. FIG. 11B also corresponds to a profile of a temperature distribution in the mounting surface 20a in a case where heating by the heater electrode 22 is uniformly performed.

As illustrated in FIG. 11B, when the uneven structure 25 is provided to the electrostatic chuck 20 in accordance with the aspect illustrated in FIG. 11A, heat resistance in the bonding sheet 40 is substantially uniform regardless of the position. This is because heat transmission from the protrusion 23 provided to have the uniform height is dominant in the manner similar to the case illustrated in FIG. 2B.

This suggests that when the degree of unevenness in the uneven structure 25 is adjusted in accordance with the thickness variation of the bonding sheet 40 while the height of the distal end surface 23e of the protrusion 23 is uniform, the temperature variation in the mounting surface 20a of the electrostatic chuck 20 can be favorably corrected even in a case where the bonding sheet 40 has the thickness variation.

However, as described above, in an actual case, the temperature (or the heat generation density) variation indeterminately occurs at a random position. Thus, it is not realistic to make the height of the distal end surface 23e differ to devotedly deal with the variation. In addition, since a degree of the thickness variation in the bonding sheet 40 varies depending on an individual member, it is not realistic to devotedly deal with the thickness variation.

Thus, the thickness distribution of the bonding sheet 40 is measured in advance of the bonding, and when the bonding sheet 40 includes the thickness variation, the high rib structure 25H and the low rib structure 25L, which have the deeper recess 24 than a depth defined by the relationship with the uneven reference line L, are also used as a constituent unit of the rib pattern to absorb the thickness variation in addition to the normal high rib structure 25H and the low rib structure 25L, in setting the rib pattern in the individual unit region RE according to the manner described above based on the temperature distribution of the mounting surface 20a of the electrostatic chuck 20 to correct the temperature variation in the mounting surface 20a. The high rib structure 25H and the low rib structure 25L having such a deep recess 24 are referred to as the thickness-absorption high rib structure 25H and the thickness-absorption low rib structure 25L, respectively. hereinafter. When the normal high rib structure 25H and the normal low rib structure 25L are referred to as the first unit structure and the second unit structure, respectively, the thickness-absorption high rib structure 25H and the thickness-absorption low rib structure 25L are also referred to as a third unit structure and a fourth unit structure, respectively. In other words, when thickness variation of the bonding sheet 40 is absorbed in addition to correction of the temperature variation, the rib pattern includes one type or plural types of unit structures in these four types of unit structures mixed at a predetermined ratio. The protrusion 23H and the recess 24H of thickness-absorption high rib structure 25H are also referred to as a third protrusion and a third recess, respectively, and the protrusion 23L and the recess 24L of the thickness-absorption low rib structure 25L are also referred to as a fourth protrusion and a fourth recess, respectively.

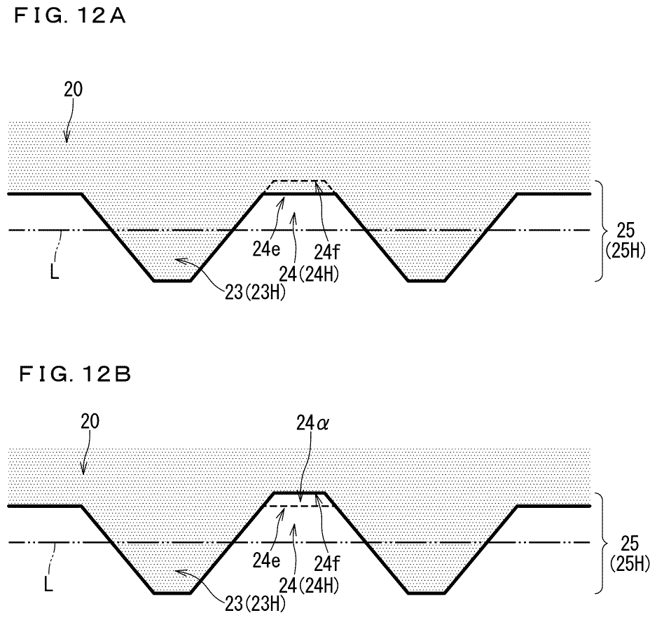

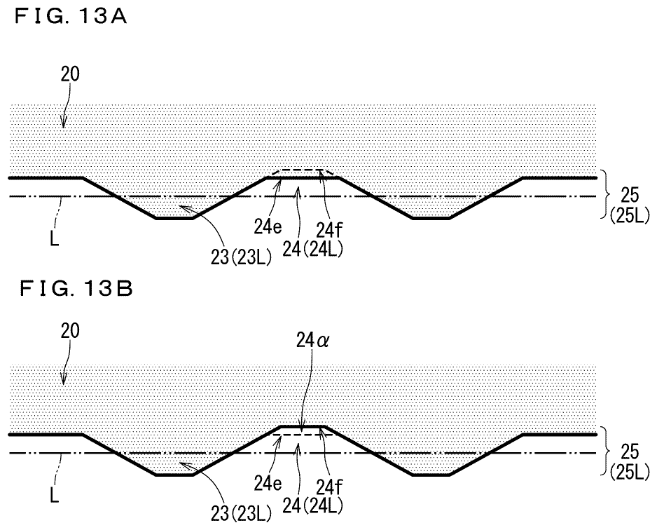

FIG. 12A and FIG. 12B are diagrams for explaining the thickness-absorption high rib structure 25H, and FIG. 13A and FIG. 13B are diagrams for explaining the thickness-absorption low rib structure 25L. As illustrated in FIG. 12A and FIG. 13A, in the thickness-absorption high rib structure 25H and the thickness-absorption low rib structure 25L, the protrusion 23 is formed in the same form as the original (without consideration of the thickness variation) protrusion 23 in the manner similar to that of the normal high rib structure 25H and the normal low rib structure 25L. In the meanwhile, the recess 24 is formed so that a bottom surface 24f thereof is deeper than the bottom surface 24e of the recess 24 in the normal high rib structure 25H and the normal low rib structure 25L defined in accordance with the position of the uneven reference line L. This configuration can be achieved by appropriately adjusting the processing condition in the laser processing described above.

Accordingly, as illustrated in FIG. 12B and FIG. 13B, in the thickness-absorption structure 25H and the thickness-absorption low rib structure 25L, a range deeper than the recess 24 in the normal high rib structure 25H and the normal low rib structure 25L serves as a thickness-absorption region 24a.

Then, in correcting the temperature variation in the mounting surface 20a, an area ratio between the normal high rib structure 25H, the normal low rib structure 25L, the thickness absorption high rib structure 25H, and the thickness absorption low rib structure 25L in the rib pattern applied to the unit region RE is differed in accordance with the temperature correction amount in the individual unit region RE specified from the temperature distribution of the mounting surface 20a in the reference electrostatic chuck and the degree of the thickness variation in the position corresponding to the individual unit region RE in the bonding sheet 40 which has been previously specified.

That is to say, although FIG. 12A, FIG. 12B, FIG. 13A, and FIG. 13B illustrate the aspect that the bottom surface 24f is formed in the deeper position than the normal bottom surface 24e in only one recess 24 and the thickness absorption region 24a is provided for simplifying the illustration, the area ratio between the thickness absorption high rib structure 25H and the thickness absorption low rib structure 25L in each unit region RE is actually set in accordance with the degree of the thickness variation in the position corresponding to the individual unit region RE, in other words, in accordance with the magnitude of the thickness variation to be absorbed in the individual unit region RE.

In such a case, the uneven structure 25 in the individual unit region RE does not necessarily correspond to the actual shape of the thickness variation in the position corresponding to the unit region RE in the bonding sheet 40. However, the area ratio between the thickness absorption high rib structure 25H and the thickness absorption low rib structure 25L gets larger in the position having the larger thickness variation. That is to say, the thickness absorption region 24a is provided over the large area. Since the bonding sheet 40 has elasticity, the position having the thickness variation favorably enters the recess 24 having the thickness absorption region 24a while being deformed by entry of the protrusion 23.

A maximum thickness adjustment amount of the bonding sheet 40 by providing the thickness absorption high rib structure 25H and the thickness absorption low rib structure 25L is equal to or larger than 2 μm. This means that the absorption amount of the thickness variation in a case where at least only one of the thickness absorption high rib structure 25H and the thickness absorption low rib structure 25L is provided to the unit region RE is 2 μm at least. In such a case, absorption of the thickness variation by the thickness absorption region 24a is effective.

Table 2 shows an example of the rib pattern set in the individual unit region RE by an area ratio between the normal high rib structure 25H (H rib), the normal low rib structure 25L (L rib), the thickness absorption high rib structure 25H (thickness absorption H rib), and the thickness absorption low rib structure 25L (thickness absorption L rib) in a case where the temperature variation in the mounting surface 20a is corrected together with the absorption of the thickness variation. Table 2 shows the area ratio of each rib structure by A, B, C, and D in this order. The state where the area ratio is 0 indicates that the rib structure is not provided.

TABLE 2

| Rib area ratio | | | Sheet thickness adjustment amount | | |
|---|---|---|---|---|---|
| A:B:C:D | | | 0 μm | 1 μm | 2 μm |
| Heat resistance | +1° | C. | 8:0:0:0 | 4:4:0:0 | 0:8:0:0 |
| adjustment | +0.5° | C. | 6:0:2:0 | 3:3:1:1 | 0:6:0:2 |
| amount | ±0° | C. | 4:0:4:0 | 2:2:2:2 | 0:4:0:4 |
| | −0.5° | C. | 2:0:6:0 | 1:1:3:3 | 0:2:0:6 |
| | −1° | C. | 0:0:8:0 | 0:0:4:4 | 0:0:0:8 |

*A: H rib, B: thickness absorption H rib, C: L rib, D: thickness absorption L rib

In the example shown by Table 2, the heat resistance adjustment amount is adjusted in five stages of +1.0° C., +0.5° C., ±0° C., −0.5° C., and −1.0° C. in correction of the temperature variation. For example, the case that the heat resistance adjustment amount is +1.0° C. corresponds to a temperature correction performed so that a temperature difference with the reference temperature in the mounting surface 20a having a lower temperature than the reference temperature is reduced by 1.0° C.

In the example shown in Table 2, a ratio between a sum (A+B) of a ratio between the normal high rib structure 25H and the thickness absorption high rib structure 25H and a sum (C+D) of a ratio between the normal low rib structure 25L and the thickness absorption low rib structure 25L is differed in five levels of 8:0, 6:2; 4:4. 2:6, and 0:8, so that the heat resistance adjustment amount is differed in the five levels described above. This indicates that the thickness absorption high rib structure 25H and the thickness absorption low rib structure 25L also function equally with the normal high rib structure 25H and the low rib structure 25L in a viewpoint of correction of temperature variation of the mounting surface 20a.

In the meanwhile, a ratio between a sum (A+C) of a ratio between the normal high rib structure 25H and the normal low rib structure 25L and a sum (B+D) of a ratio between the thickness absorption high rib structure 25H and the thickness absorption low rib structure 25L is differed by 8:0, 4:4, and 0:8, so that the sheet thickness adjustment amount is differed in three levels of 0 μm, 1 μm, and 2 μm.

Accordingly, any one of 15 rib patterns is applied to the individual unit region RE in accordance with the temperature distribution of the mounting surface 20a in the reference electrostatic chuck 20 and the thickness variation distribution in the bonding sheet 40 which has been previously specified: thus, the temperature variation in the mounting surface 20a can be corrected even when the bonding sheet 40 includes thickness variation.

It is confirmed that increase of temperature compared with the case with no thickness variation is limited to 0.1° C. when the rib pattern of A:B:C:D=0:8:0:0 is applied to the unit region RE where the temperature in a corresponding position in the mounting surface 20a is increased by 1° C. when the rib pattern of A:B:C:D=8:0:0:0 is applied.

It is also confirmed that increase of temperature compared with the case with no thickness variation is limited to 0.4° C. when the rib pattern of A:B:C:D=0:0:0:8 is applied, in such a case where the temperature in a corresponding position in the mounting surface 20a is increased by 1° C. when the rib pattern of A:B:C:D=0:0:8:0 is applied.

As described above, according to the present embodiment, when the uneven structure is provided to the bonding surface bonded to the boning sheet of the electrostatic chuck in the wafer mount having the configuration that the electrostatic chuck and the cooling plate are bonded by the bonding sheet, achieved is the wafer mount excellent in heat conductivity compared with the case with no uneven structure.

That is to say, since heat transmission from the protrusion is dominant in heat transmission from the electrostatic chuck to the cooling plate, heat transmission from the electrostatic chuck to the cooling plate can be effectively generated compared with the case with no uneven structure.

Furthermore, since the distance from the distal end surface of the protrusion to the cooling plate is uniformed at least in the range of the uneven structure, heat transmission from the electrostatic chuck to the cooling plate via the bonding sheet can be uniformed.

In addition, with varying the distance from the distal end surface of the protrusion to the cooling plate, the degree of heat transmission from the electrostatic chuck to the cooling plate via the bonding sheet can be adjusted in accordance with the position. In utilizing this, the temperature variation in the mounting surface can be corrected with differentiating the manner of formation of the uneven structure in accordance with the temperature distribution in the mounting surface in the case with no uneven structure. With adjusting the depth of the recess in accordance with the thickness variation of the bonding sheet, the temperature variation in the mounting surface can be corrected also in a case where the bonding sheet includes the thickness variation.

### Modification Example

Although the rib structure that the protrusion and the recess are linearly and alternately located in a plan view as the uneven structure in the embodiment described above, the uneven structure for uniforming heat is not limited thereto.

For example, applicable is an aspect that the protrusion is provided in a lattice form in a plan view and the recess is located between the lattice made by the protrusion or an aspect that the protrusion and the recess in the embodiment are switched.

Also applicable is an aspect that dot-like (for example, a circular shape, a rectangular shape, or the other polygonal shape) protrusions are periodically and discretely located in a lattice point position in a plan view and an area around the protrusions constitutes a recess.

The effect similar to that of the embodiment described above can be obtained in any of these aspects as long as the protrusion and the recess are provided to have the uneven reference surface described above.

In the embodiment described above, the uneven structure is provided to correct the temperature variation in the whole mounting surface 20a having a circular shape in a plan view. Thus, the above configuration is based on the premise that the height of the distal end surface of the protrusion in the range of each high rib structure and low rib structure is uniformed. However, an outer perimeter of the mounting surface within a 10% range may be excluded from a scope of such uniformization.

The height of the distal end surface of the protrusion in the range of each high rib structure and low rib structure is preferably the same from a viewpoint of reliably uniforming heat transmission. However, also application in an actual use is an aspect that the height of the distal end surface of the protrusion has variation within 5 μm as long as balance of entry of the protrusion into the bonding sheet and entry of the bonding sheet into the recess is ensured.

In the embodiment described above, the high rib structure and the low rib structure having the unevenness heigh different from each other in the uneven structure is combined to correct the temperature variation in the mounting surface. However, in place of this configuration, also applicable is an aspect that two types of rib structures having the same distance from the distal end surface of the protrusion to the cooling plate and the different width of the distal end surface are combined to achieve a difference of heat transmission in the bonding sheet. However, also in such a case, the pitch of the protrusion is preferably equal to or smaller than 300 μm by a reason similar to that of the embodiment described above.

Achieved in the embodiment described above is the configuration of further dealing with the thickness variation of the bonding sheet in the premise of correcting the temperature variation in the mounting surface. However, it is possible to deal with only the thickness variation of the bonding sheet when correction of temperature variation in the mounting surface is not necessary. For example, considered is an aspect that only the normal low rib structure 25L and the thickness absorption low rib structure 25L are mixed at a predetermined ratio in accordance with the thickness variation of the bonding sheet 40. The temperature itself of the mounting surface in such a case can be adjusted by adjusting heater power.

What is claimed is:

1. A wafer mount to which a wafer is mounted and fixed, comprising:
an electrostatic chuck including:
a ceramics base body including a wafer mounting surface; and
an ESC electrode and a heater electrode each buried inside the ceramics base body;
a cooling plate made of metal; and
a bonding sheet made of resin sandwiched between the electrostatic chuck and the cooling plate to bond the electrostatic chuck and the cooling plate, wherein
a bonding surface of the electrostatic chuck bonded to the bonding sheet has an uneven structure made up of one type or plural types of unit structures, and
in the uneven structure, a protrusion is provided at a pitch equal to or larger than 100 μm and equal to or smaller than 300 μm, and the bonding surface includes a distal end surface of the protrusion.

2. The wafer mount according to claim 1, wherein
a distance from a distal end of the protrusion to the cooling plate is uniform in each of the one type or plural types of unit structures.

3. The wafer mount according to claim 1, wherein
the bonding surface of the electrostatic chuck has the plural types of unit structures, and
a distance from the distal end of the protrusion to the cooling plate is different in each of the plural types of unit uneven structures.

4. The wafer mount according to claim 1, wherein
in the uneven structure, the protrusion having a linear shape in a plan view and a recess having a linear shape in a plan view are alternately and periodically provided.

5. The wafer mount according to claim 4, wherein
the bonding surface of the electrostatic chuck is made up of a plurality of unit regions,
the plural types of unit structures include:
a first unit structure having a first protrusion constituting the protrusion; and
a second unit structure having a second protrusion constituting the protrusion,
a distance from a distal end of the first protrusion to the cooling plate and a distance from a distal end of the second protrusion to the cooling plate are different from each other,
the first unit structure and the second unit structure are mixed at a predetermined ratio in each of the plurality of unit regions, and
the predetermined ratio in each of the plurality of unit regions is defined in accordance with a reference temperature distribution occurring in the mounting surface when power conduction is performed on the heater electrode of the wafer mount in which the bonding surface of the electrostatic chuck is flat.

6. The wafer mount according to claim 4, wherein
the bonding surface of the electrostatic chuck is made up of a plurality of unit regions,
the plural types of unit structures include:
a first unit structure made up of a first protrusion constituting the protrusion and a first recess constituting the recess;
a second unit structure made up of a second protrusion constituting the protrusion and having a different distance to the cooling plate from the first protrusion and a second recess constituting the recess;
a third unit structure made up of a third protrusion having a same distance to the cooling plate as the first protrusion and a third recess having a larger depth than the first recess,
a fourth unit structure made up of a fourth protrusion having a same distance to the cooling plate as the second protrusion and a fourth recess having a larger depth than the second recess,
the first to fourth unit structures are mixed at a predetermined ratio in each of the plurality of unit regions, and
the predetermined ratio in each of the plurality of unit regions is defined in accordance with a reference temperature distribution occurring in the mounting surface when power conduction is performed on the heater electrode of the wafer mount in which the bonding surface of the electrostatic chuck is flat and a thickness in a position corresponding to each of the plurality of unit regions in the bonding sheet.

7. A method of manufacturing a wafer mount to which a wafer is mounted and fixed, comprising steps of:
a) step of preparing an electrostatic chuck including a ceramics base body having a wafer mounting surface and an ESC electrode and a heater electrode each buried inside the ceramics base body; and
b) bonding the electrostatic chuck and a cooling plate made of metal by a bonding sheet made of resin sandwiched therebetween, wherein
the step a) includes the step of:
a-1) alternately and periodically providing a protrusion and a recess to a bonding surface of the electrostatic chuck bonded to the bonding sheet to provide an uneven structure,
the step a-1) is at least one of:
a first step of reducing variation in a temperature distribution occurring in the mounting surface; and
a second step of making the recess absorb thickness variation when the bonding sheet includes thickness variation, and
in the step b), a distal end surface of the protrusion is included in the bonding surface.

8. The method of manufacturing the wafer mount according to claim 7, wherein
in the step a-1), the uneven structure is provided to be made up of one type or plural types of unit structures, and a pitch of each of the protrusion and the recess is set to be equal to or larger than 100 μm and equal to or smaller than 300 μm.

9. The method of manufacturing the wafer mount according to claim 8, wherein
in the step a-1), a distance from a distal end of the protrusion to the cooling plate is set to be uniform in each of the one type or plural types of unit structures.

10. The method of manufacturing the wafer mount according to claim 8, wherein
in the step a-1), the plural types of unit structures are provided to the bonding surface of the electrostatic chuck, and
a distance from the distal end of the protrusion to the cooling plate is differentiated in each of the plural types of unit uneven structures.

11. The method of manufacturing the wafer mount according to claim 8, wherein
in the step a-1), the protrusion and the recess are linearly provided.

12. The method of manufacturing the wafer mount according to claim 11, wherein
when the step a-1) is the first step,
the bonding surface of the electrostatic chuck is virtually sectioned into a plurality of unit regions,
the plural types of unit structures include:
a first unit structure having a first protrusion constituting the protrusion; and
a second unit structure having a second protrusion constituting the protrusion,
a distance from a distal end of the first protrusion to the cooling plate and a distance from a distal end of the second protrusion to the cooling plate are differentiated from each other,
the first unit structure and the second unit structure are mixed at a predetermined ratio in each of the plurality of unit regions, and
the predetermined ratio in each of the plurality of unit regions is set so that temperature variation in a temperature distribution occurring in the mounting surface when power conduction is performed on the heater electrode is reduced lower than previously measured temperature variation in a reference temperature distribution occurring in the mounting surface when power conduction is performed on the heater electrode of the wafer mount in which the bonding surface of the electrostatic chuck is flat.

13. The method of manufacturing the wafer mount according to claim 11, wherein
when the step a-1) is the first and second steps,
the bonding surface of the electrostatic chuck is virtually sectioned into a plurality of unit regions,
the plural types of unit structures include:
a first unit structure made up of a first protrusion constituting the protrusion and a first recess constituting the recess;
a second unit structure made up of a second protrusion constituting the protrusion and having a different distance to the cooling plate from the first protrusion and a second recess constituting the recess;
a third unit structure made up of a third protrusion having a same distance to the cooling plate as the first protrusion and a third recess having a larger depth than the first recess; and
a fourth unit structure made up of a fourth protrusion having a same distance to the cooling plate as the second protrusion and a fourth recess having a larger depth than the second recess,
the first to fourth unit structures are mixed at a predetermined ratio in each of the plurality of unit regions, and
the predetermined ratio in each of the plurality of unit regions is set so that temperature variation in a temperature distribution occurring in the mounting surface when power conduction is performed on the heater electrode is reduced lower than previously measured temperature variation in a reference temperature distribution occurring in the mounting surface when power conduction is performed on the heater electrode of the wafer mount in which the bonding surface of the electrostatic chuck is flat, and also in accordance with a thickness corresponding to each of the plurality of unit regions of the bonding sheet.

14. The wafer mount according to claim 2, wherein
in the uneven structure, the protrusion having a linear shape in a plan view and a recess having a linear shape in a plan view are alternately and periodically provided.

15. The wafer mount according to claim 14, wherein
the bonding surface of the electrostatic chuck is made up of a plurality of unit regions,
the plural types of unit structures include:
a first unit structure having a first protrusion constituting the protrusion; and
a second unit structure having a second protrusion constituting the protrusion,
a distance from a distal end of the first protrusion to the cooling plate and a distance from a distal end of the second protrusion to the cooling plate are different from each other,
the first unit structure and the second unit structure are mixed at a predetermined ratio in each of the plurality of unit regions, and
the predetermined ratio in each of the plurality of unit regions is defined in accordance with a reference temperature distribution occurring in the mounting surface when power conduction is performed on the heater electrode of the wafer mount in which the bonding surface of the electrostatic chuck is flat.

16. The wafer mount according to claim 14, wherein
the bonding surface of the electrostatic chuck is made up of a plurality of unit regions,
the plural types of unit structures include:
a first unit structure made up of a first protrusion constituting the protrusion and a first recess constituting the recess;
a second unit structure made up of a second protrusion constituting the protrusion and having a different distance to the cooling plate from the first protrusion and a second recess constituting the recess;
a third unit structure made up of a third protrusion having a same distance to the cooling plate as the first protrusion and a third recess having a larger depth than the first recess; and
a fourth unit structure made up of a fourth protrusion having a same distance to the cooling plate as the second protrusion and a fourth recess having a larger depth than the second recess,
the first to fourth unit structures are mixed at a predetermined ratio in each of the plurality of unit regions, and
the predetermined ratio in each of the plurality of unit regions is defined in accordance with a reference temperature distribution occurring in the mounting surface when power conduction is performed on the heater electrode of the wafer mount in which the bonding surface of the electrostatic chuck is flat and a thickness in a position corresponding to each of the plurality of unit regions in the bonding sheet.

17. The wafer mount according to claim 3, wherein
in the uneven structure, the protrusion having a linear shape in a plan view and a recess having a linear shape in a plan view are alternately and periodically provided.

18. The wafer mount according to claim 17, wherein
the bonding surface of the electrostatic chuck is made up of a plurality of unit regions,
the plural types of unit structures include:
a first unit structure having a first protrusion constituting the protrusion; and
a second unit structure having a second protrusion constituting the protrusion,
a distance from a distal end of the first protrusion to the cooling plate and a distance from a distal end of the second protrusion to the cooling plate are different from each other,
the first unit structure and the second unit structure are mixed at a predetermined ratio in each of the plurality of unit regions, and
the predetermined ratio in each of the plurality of unit regions is defined in accordance with a reference temperature distribution occurring in the mounting surface when power conduction is performed on the heater electrode of the wafer mount in which the bonding surface of the electrostatic chuck is flat.

19. The wafer mount according to claim 17, wherein
the bonding surface of the electrostatic chuck is made up of a plurality of unit regions,
the plural types of unit structures include:
a first unit structure made up of a first protrusion constituting the protrusion and a first recess constituting the recess;
a second unit structure made up of a second protrusion constituting the protrusion and having a different distance to the cooling plate from the first protrusion and a second recess constituting the recess;
a third unit structure made up of a third protrusion having a same distance to the cooling plate as the first protrusion and a third recess having a larger depth than the first recess; and
a fourth unit structure made up of a fourth protrusion having a same distance to the cooling plate as the second protrusion and a fourth recess having a larger depth than the second recess,
the first to fourth unit structures are mixed at a predetermined ratio in each of the plurality of unit regions, and
the predetermined ratio in each of the plurality of unit regions is defined in accordance with a reference temperature distribution occurring in the mounting surface when power conduction is performed on the heater electrode of the wafer mount in which the bonding surface of the electrostatic chuck is flat and a thickness in a position corresponding to each of the plurality of unit regions in the bonding sheet.

20. The method of manufacturing the wafer mount according to claim 9, wherein
in the step a-1), the protrusion and the recess are linearly provided.
